(19) United States
(12) Patent Application Publication
(10) Pub. No.: US 2025/0113443 A1
(43) Pub. Date: Apr. 3, 2025

(54) ELECTRONIC DEVICES, SOCKET LOADING MECHANISMS, AND METHODS

(71) Applicants: Shyamjith Mohan, North Plains, OR (US); Raghavendra Rao, Bangalore (IN); Rob Sims, Forest Grove, OR (US); Prasanna Pichumani, Bangalore (IN); Vijith Halestoph R, Bangalore (IN); Kylee Smith, Tigard, OR (US)

(72) Inventors: Shyamjith Mohan, North Plains, OR (US); Raghavendra Rao, Bangalore (IN); Rob Sims, Forest Grove, OR (US); Prasanna Pichumani, Bangalore (IN); Vijith Halestoph R, Bangalore (IN); Kylee Smith, Tigard, OR (US)

(21) Appl. No.: 18/979,185

(22) Filed: Dec. 12, 2024

(51) Int. Cl. H05K 3/32; H05K 1/18

(52) U.S. Cl. CPC H05K 3/32; H05K 1/18; H05K 2201/10325

(57) ABSTRACT

Systems, apparatus, articles of manufacture, and methods are disclosed to load an integrated circuit (IC) into a socket. An example apparatus to load an IC in a socket includes: a collar; a tightener; a ramp carried by at least one of the collar or the tightener; and a cam carried by at least another one of the collar or the tightener, the cam engageable with the ramp, rotation of the tightener to cause relative movement between the cam and the ramp to displace the collar to apply a load to the IC.

### BACKGROUND

A microprocessor such as a central processing unit (CPU) is coupled to a printed circuit board (PCB) via a socket. The socket provides mechanical and electrical connections between the CPU and the PCB. A loading mechanism is used to press the CPU into the socket.

### BRIEF DESCRIPTION OF THE DRAWINGS

FIG. 1 illustrates a collection of components that are used in example socket loading mechanisms in accordance with teachings of this disclosure.

FIG. 2 is a perspective view of the collection of components of FIG. 1 assembled into an example socket loading mechanism.

FIG. 3 is an isometric section view of the socket loading mechanism of FIG. 2.

FIG. 4A illustrates an example collar and example tightener of the socket loading mechanism of FIG. 2.

FIG. 4B is an enlarged view of the engagement of the collar and the tightener ring.

FIG. 4C is a top view of the collar.

FIG. 5 is a perspective view of the socket loading mechanism of FIG. 2 with an alternatively configured tightener and example heat sink.

FIG. 6 illustrates an example process for loading an example integrated circuit (IC) into an example socket on an example printed circuit board with the socket loading mechanism of FIG. 2.

FIG. 7A illustrates an example compression plate in an alternative socket loading mechanism.

FIG. 7B is an enlarged view of an example cam on the compression plate of FIG. 7A.

FIG. 8A illustrates an example loading plate for use in the alternative socket loading mechanism of FIG. 7A.

FIG. 8B is an enlarged view of an example ramp on the loading plate of FIG. 8A.

FIG. 9 is a cross-sectional view of the compression plate of FIG. 7A engaged with the loading plate of FIG. 8A.

FIG. 10A illustrates the compression plate of FIG. 7A engaged with the loading plate of FIG. 8A in an unloaded position.

FIG. 10B illustrates the compression plate of FIG. 7A engaged with the loading plate of FIG. 8A in a loaded position.

FIG. 11A illustrates the footprint of a conventional socket loading mechanism on a printed circuit board.

FIG. 11B illustrates the footprint of the socket loading mechanism of FIG. 2 on a printed circuit board.

In general, the same reference numbers will be used throughout the drawing(s) and accompanying written description to refer to the same or like parts. The figures are not necessarily to scale. Instead, the thickness of the layers or regions may be enlarged in the drawings.

### DETAILED DESCRIPTION

A printed circuit board (PCB) is a substrate that, among other things, mechanically supports components in electronic devices. Mounting holes are drilled into the PCB for standouts or other posts to mount components to the PCB. Wires or traces run through the PCB to electronically connect different components of the electronic device. The wires are routed around the holes. Thus, the more mounting holes there are in a PCB, the less area of the PCB is available for wiring.

A socket is a component which is often mounted to the PCB. An integrated circuit (IC), sometimes referred to as a chip, is coupled to the socket. ICs are contained in packages. An example IC may include one or more of a microprocessor, a central processing unit (CPU), a graphics processing unit (GPU), a field programmable gate array (FPGA), a system on a chip (SoC), or other components and/or processor circuitry. The IC includes a plurality of pins that are to be aligned with the socket when the IC is coupled to the socket. A socket loading mechanism may be used to couple the IC to the socket. Some socket loading mechanisms include components such as hinges and levers that are used to load the IC. Such socket loading mechanisms are typically designed to provide a load for a specific IC and, thus, are not scalable for next-generation processors or other ICs. In addition, such socket loading mechanisms use space on the PCB (known as a keep-out zone) that cannot be used for wiring or placement of other components.

Mounting holes and other keep-out zones cause other components such as memories, power supplies, discrete electrical components, etc. to be moved farther away from the IC. When components are moved farther away, additional components such as decoupling capacitors are needed for the same electrical load line. In addition, when a power supply is placed farther away from the IC, the power loss across the PCB increases, which decreases the efficiency of power supply delivery. In addition, the PCB layout is more complicated with contorted circuit paths to avoid the mounting holes and/or other keep-out zones.

Example socket loading mechanisms disclosed herein enable the reduction of mounting holes associated with the socket. Example socket loading mechanisms disclosed herein also create fewer keep-out zones. Thus, there is easier, less complex, and better routing of the wiring in the PCB. In addition, components of the electronic device, including memories, power supplies, capacitors, etc. can be closer to the socket. With better proximity to the socket, there is less power loss and a reduced number of decoupling capacitors than designs that have more keep-out zones with components farther from the socket.

Also, the electrical performance of the power supply is improved because the distance between the power supply and the load (e.g., the IC) is reduced. Static load line resistance is reduced. Reduction in the distance between the power supply and the load (e.g., the IC) also reduces plane inductance.

Examples disclosed herein use a ramp mechanism that generates a force to load an IC into a socket. Example socket loading mechanisms disclosed herein have a smaller footprint than known designs, which produce fewer keep-out zones. In addition, example socket loading mechanisms disclosed herein can produce loads that are scalable across different ICs including for next generation ICs.

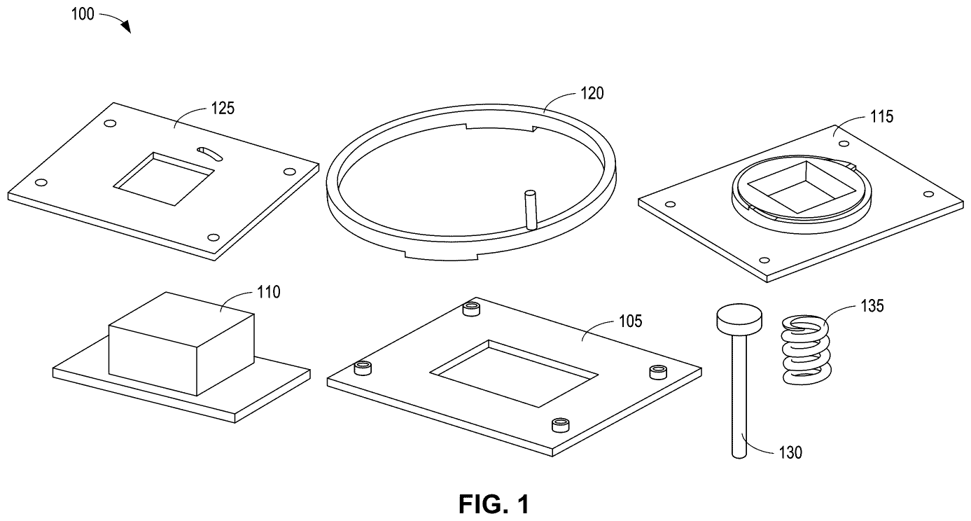

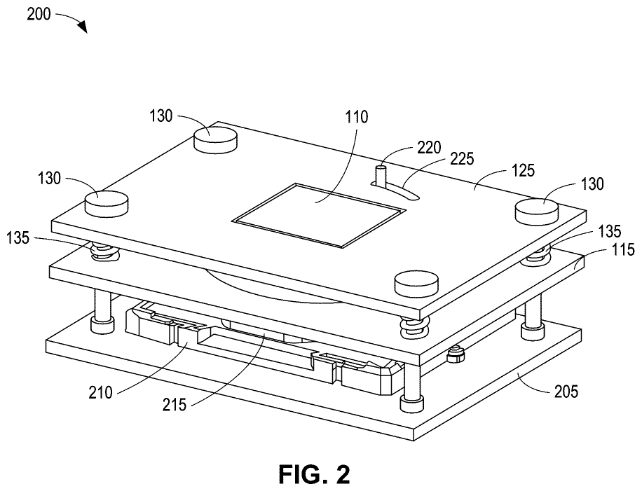

FIG. 1 illustrates a collection of components 100 of socket loading mechanisms in accordance with teachings of this disclosure. The components 100 include an example backplate 105, an example heat sink 110, an example collar 115, an example tightener 120, an example sleeve 125, an example post 130 and an example spring 135. FIG. 2 is a perspective view of the components 100 of FIG. 1 assembled into an example socket loading mechanism 200 on an example printed circuit board 205. The printed circuit board 205 supports an example socket 210 into which an example IC 215 is loaded.

In the illustrated example, a handle 220 is coupled to and/or integral with the tightener 120. In this example, the handle 220 extends through an example slot 225 in the sleeve 125. The handle 220 is used to move the tightener 120. For example, the handle 220 facilitates rotation of the tightener 120. In examples in which the tightener 120 is rotated, the slot 225 may be in the shape of an arc through which the handle 220 travels. In other examples, where a tightener 120 is laterally moved or slid, the slot 225 may be an elongated shape such as an oblong oval. In some examples, there is more than one handle 220 to add additional leverage. More handles can reduce the force (e.g., the human effort) needed to operate the socket loading mechanism 200. In some examples, the force imparted on the handle 220 is less than the force used to compress pins on the socket 210. In some examples, the force imparted on the handle 220 is less than 100 pound-force (lbf)

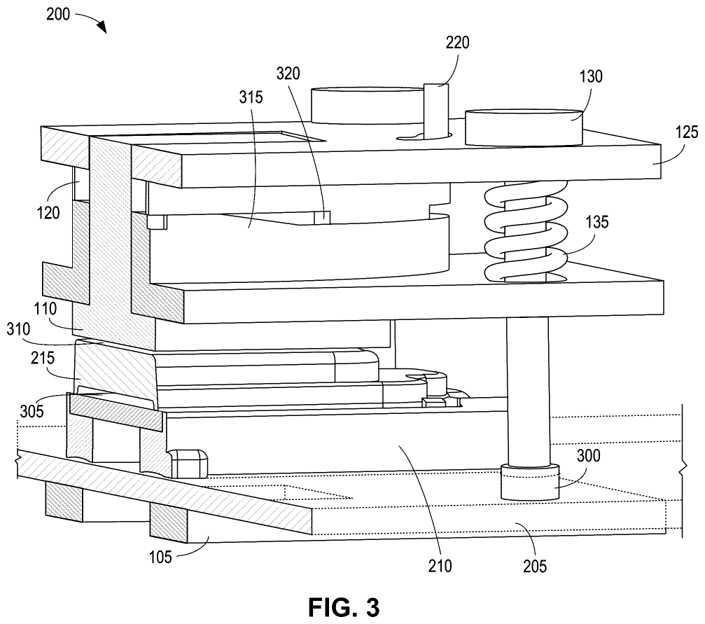

FIG. 3 is an isometric section view of the example socket loading mechanism 200 of FIG. 2. The backplate 105 supports the socket loading mechanism 200 from one side of the printed circuit board 205. For example, the post 130 extends from the sleeve 125 into an example standoff 300 on the printed circuit board 205 and is secured with the backplate 105. In other examples, the post 130 is secured into the standoff 300. The example of FIGS. 2 and 3 show four posts 130. Other examples include any other number of posts 130 such as three, two, etc. The posts 130 hold the socket loading mechanism 200 on the printed circuit board 205. The posts 130 can be screws, bolts, or other fasteners.

In the illustrated example, the socket 210 is mounted to the printed circuit board 205. The IC 215 is positioned in the socket 210 with example first thermal interface material 305 positioned therebetween. In the illustrated example, there is an example second thermal interface layer 310 between the IC 215 and the heat sink 110. In some examples, the first thermal interface layer 305 and/or the second thermal interface layer 310 include a material that fills the interface and creates a smooth surface between the IC 215 and the socket 210 and/or the heat sink 110. In some examples, the first thermal interface layer 305 and/or the second thermal interface layer 310 include one or more of a solder, an adhesive, a grease, a silicone oil, a gel, a phase change material, a polymer matrix, a silicon resin, an epoxy, a thermally conductive material, a polymer film, a metal foil, a glass, and/or a pad.

The heat sink 110 of this example is positioned at, near, on, and/or adjacent to the IC 215. The heat sink 110 facilitates dissipation of thermal energy away from the IC 215, thereby cooling the electronics. In the illustrated example, a first portion of the heat sink 110 is positioned between the IC 215 and the collar 115. A second portion of the heat sink 110 extends along a longitudinal axis or a central axis of the socket loading mechanism 200 and through a first aperture of the collar 115, a second aperture of the tightener 120, and a third aperture of the sleeve 125. Thus, the second portion of the heat sink 110 is surrounded by the collar 115, the tightener 120, and the sleeve 125.

The collar 115 and the tightener 120 interface between the first portion of the heat sink 110 and the sleeve 125. The collar 115 includes an example ramp 315, and the tightener 120 includes an example cam 320. The tightener 120 is movably positioned on the collar 115. For example, the tightener 120 is rotatable on the collar 115. In the illustrated example, the tightener 120 is rotatable about the central axis. In some examples, the tightener 120 is rotated by manipulation of the handle 220. Specifically, a user, a robot, or other machine, can use the handle 220 to rotate the tightener 120. In the illustrated example, the tightener 120 is ring-shaped. In other examples, the tightener 120 may be a plate, a disc, or other regular or irregular shape.

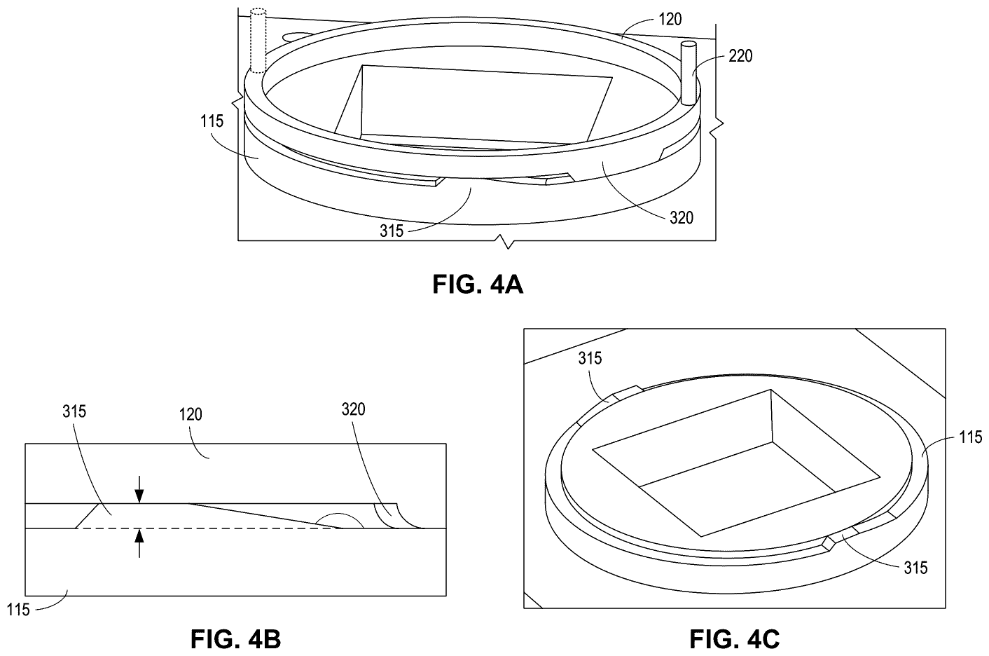

FIG. 4A illustrates a perspective view of the engagement of the collar 115 and the tightener 120. As the tightener 120 rotates, the cam 320 engages the ramp 315. FIG. 4B is an enlarged side view showing the engagement of the collar 115 and the tightener 120 as the cam 320 approaches the ramp 315. During rotation of the tightener 120, the cam 320 continues to engage the ramp 315. The engagement of the cam 320 with the ramp 315 causes displacement of the collar 315 along the axis from a first position to a second position and toward the backplate 105, the printed circuit board 205, and all components therebetween. The displacement of the collar 115 generates or creates a load or force on the IC 215. The force on the IC 215 presses or loads the IC 215 into the socket 210.

In some examples, the collar 115 moves the first portion of the heat sink 110 toward the socket 210. The surface of the first portion of the heat sink 110 facing the IC 215 provides a uniform application of the load onto the IC 215. The uniform application of the load on the IC 215 reduces and/or prevents warpage of the package of the IC 215 during operation of the socket loading mechanism 200. Warpage is more likely to occur when the IC 215 is loaded into the socket 210 by forces applied on the sides of the package of the IC 215 such as occur in conventional designs.

FIG. 4C is a top view of the collar 315. In the illustrated example, there are two ramps 315. In other examples, there may be any other numbers of ramps 315 including one, three, four, six etc. In some examples, there are a number of cams 320 on the tightener 220 that match the number of ramps 315 on the collar 115. In other examples, there are a different number of cams 320 than there are ramps 315. For example, there may be one cam 320 on the tightener 120 and a plurality of ramps 315 on the collar 115. Also, in some examples, there may be one ramp 315 on the collar 315 and a plurality of cams 320 on the tightener 120. The use of multiple ramps 315 and/or cams 320 can split the load on each individual ramp 315 and/or cam 320 to improve leverage. The improved leverage reduces the effort used (e.g., reduces the amount of force) to activate the socket loading mechanism 200.

The profile of the ramp 315 is angled. The amount of force on the IC 215 as the collar 115 is displaced is based on a magnitude of the angle. The dimensions of the ramp 315 (such as height and/or angle) can be adjusted based on the load requirements for loading the IC 215 into the socket 210. In some examples, a ramp 315 with a height of about 1.0 millimeters, could provide a load of about 360 lbf on the IC 215. By way of comparison, a force of 150 lbf typically is used to load a chip in a socket in desktop computers. Additionally or alternatively, in some examples, the amount of force on the IC 215 as the collar 115 is displaced is based the rotation angle. Thus, the rotation angle can be adjusted or designed based on the amount of force to be used to load the socket 210.

In some examples, the posts 130 and/or the sleeve 125 prevents or limits displacement of the tightener 120. For example, the sleeve 125 inhibits movement of the tightener 120 along the axis in the direction away from the printed circuit board 205. Maintenance of the lateral or vertical position of the tightener 120 relative to the printed circuit board 205 and other components of the socket loading mechanism 200 directs the load generated by the engagement of the cam 320 with the ramp 315 onto the IC 215.

In the illustrated example, one or more of the posts 130 extends through the collar 115. The post 130 prevents the collar 315 from rotating as the cam 320 engages the ramp 320. Also, in some examples, the spring 135 supplies additional load to the collar 315 to move the collar 315 toward the socket 210. In such examples, as the collar 315 is displaced toward the socket 210, the spring 135 expands.

In some examples, the load on the IC 215 can be released. For example, the handle 220 can be moved to rotate the tightener 120 around the axis of rotation in the opposite direction of that employed to load the IC 215. Rotation in this direction causes the cam 320 to disengage the ramp 315. With the ramp disengaged, the collar 115 can be displaced toward the tightener 120, and the load on the IC 215 is reduced (e.g., released). The posts 130 can be removed to remove the socket loading mechanism 200 from the printed circuit board 205. With the socket loading mechanism 200 removed, the IC 215 can be removed, replaced, and/or otherwise serviced.

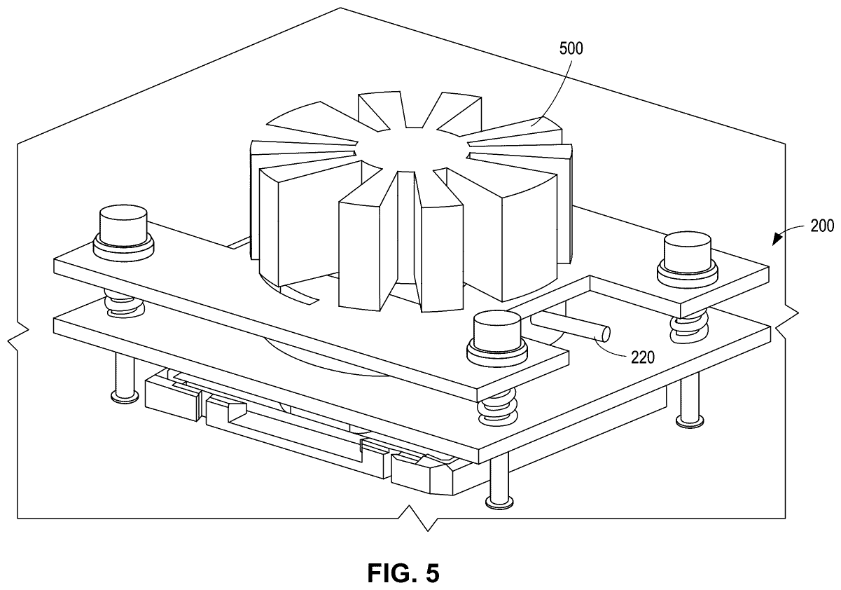

FIG. 5 is a perspective view of the socket loading mechanism 200 of FIG. 2 with an alternatively configured tightener 120 and an example external heat sink 500. The term “external” indicates that the heart sink 500 is positioned on, adjacent, and/or near the socket loading mechanism 200 but not within the stack of the socket loading mechanism 200 between the sleeve 125 and the socket 210. The external heat sink 500 is in addition to the heat sink 110 that is used in the socket loading mechanism 200. In this example, the handle 220 of the tightener 120 is positioned on the side of the tightener 120. The position of the handle 220 on the side of the tightener 120 enables access to and manipulation of the handle 220 while the external heat sink 500 is positioned on the sleeve 125. Thus, in this example, there is no interference between the handle 220 and the external heat sink 500. In some examples, the external heat sink 500 is coupled directly to the core or second portion of the heat sink 110 that extends to the sleeve 125. In some examples, a thermal interface material is not used between the external heat sink 500 and the heat sink 110.

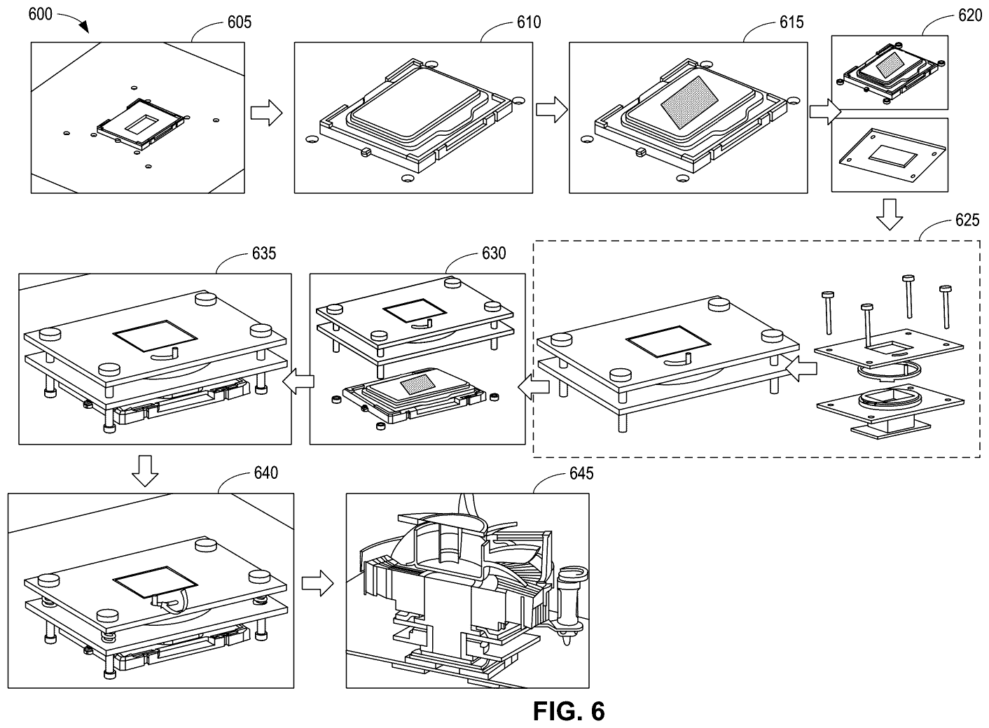

FIG. 6 illustrates an example process 600 for loading an example IC into an example socket on an example printed circuit board with the socket loading mechanism of FIG. 2. In the example process 600, the socket 210 is positioned and/or fastened to the printed circuit board 205 (block 605). The IC 215 is placed on or into the socket 210 (block 610). The first thermal interface material 305 is placed on the IC 215 (block 615). The backplate 105 is assembled and/or fastened to the printed circuit board 205 (block 620).

The process 600 also includes assembling the heat sink 110, the collar 115, the tightener 120, the sleeve 125, the posts 130, and springs 135 to form a sub-assembly of the socket loading mechanism 200 (block 625). The sub-assembly of the socket loading mechanism 200 is coupled to the printed circuit board 205 and the backplate 105 (block 630). The posts 130 are tightened in accordance with the designed torque specification (block 635).

The handle 220 is manipulated by the user to turn the tightener 120 (block 640). Rotation of the tightener 120 causes the cams 320 to engage the ramps 315. The engagement of the cams 320 with the ramps 320 generates a load that is transferred via the collar 315 and the heat sink 110 to the IC 215 to load the IC 215 into the socket 210. The operation of the socket loading mechanism 200 is complete with the IC 215 loaded into the socket. In some examples, the process 600 additionally includes adding one or more external heat sinks or other thermal solutions such as a fan (block 645).

Further, although the example process 600 is described with reference to the flowchart(s) illustrated in FIG. 6, many other methods of implementing examples disclosed herein may alternatively be used. For example, the order of execution of the blocks of the flowchart(s) may be changed, and/or some of the blocks described may be changed, eliminated, or combined.

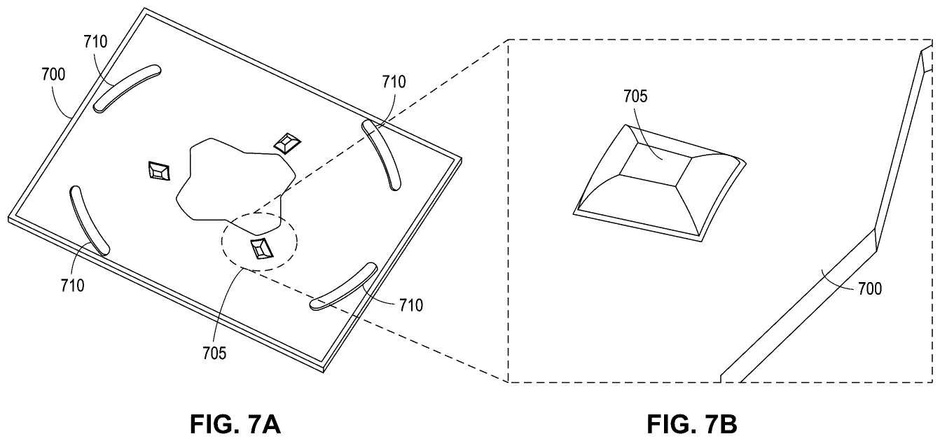

The example of FIGS. 1-4C includes a ring-shaped tightener 120 and a ring-shaped collar 215, FIGS. 7A-9 illustrate alternative designs that may be used in a socket loading mechanism. FIG. 7A illustrates an example compression plate 700 that may be used as the tightener 120. The compression plate 700 includes a plurality of protrusions or cams 705. FIG. 7B is an enlarged view of one of the cams 705. The compression plate 700 also includes a plurality of slots 710. The features of the cams 320 disclosed above including, for example, shape, geometry, placement, numbers, and functionality apply to the cams 705 of this example.

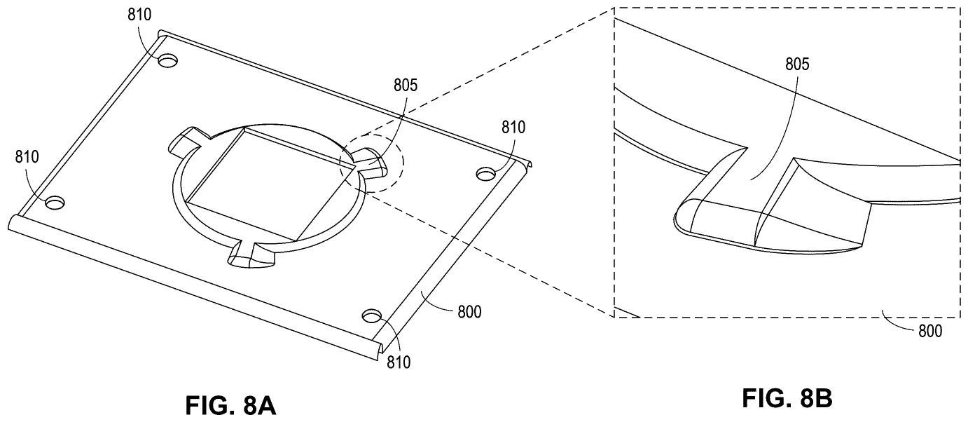

FIG. 8A illustrates an example loading plate 800 that may be used at the collar 115. The loading plate 800 includes a plurality of ramps 805. FIG. 8B is an enlarged view of one of the ramps 805. The loading plate 800 also includes a plurality of apertures 810. The features of the ramps 315 disclosed above including, for example, shape, geometry, placement, numbers, and functionality apply to the ramps 805 of this example.

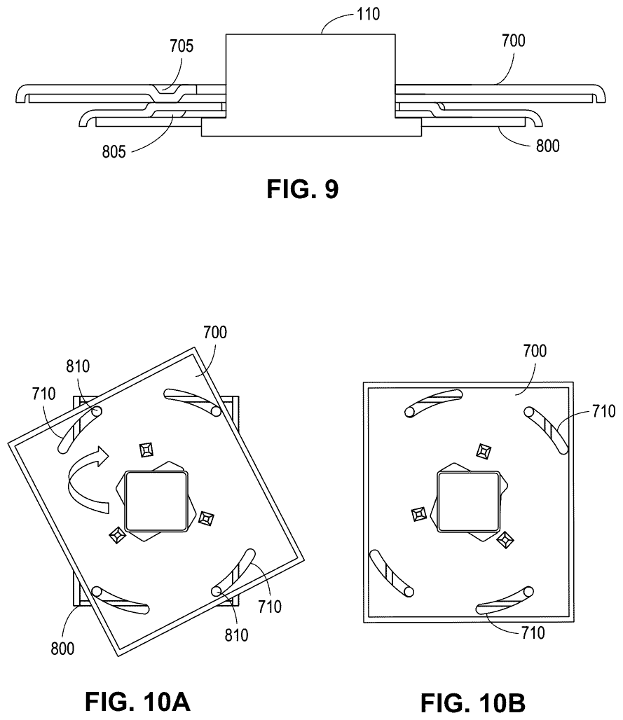

During the loading of the IC 215 in the socket 210, the compression plate 700 is rotated relative to the loading plate 800. This causes the cams 705 to engage the ramps 805 as shown in FIG. 9. The engagement of the cams 705 and ramps 805 generates a force and causes displacement of the loading plate 800. The displacement of the loading plate 800 also displaced the heat sink 110 toward the IC 215 (similar to the structure of FIG. 3). The heat sink 110 transfers the load to the IC 215 to load the IC 215 in the socket 210.

FIG. 10A illustrates the compression plate 700 engaged with the loading plate 800 in an unloaded position. FIG. 10B illustrates the compression plate 700 engaged with the loading plate 800 in a loaded position. The posts 130 extend through the slots 710 and the apertures 810. The posts 130 hold the loading plate 800 in position during engagement of the cams 705 and ramps 805. In other words, the posts 130 prevent rotation of the loading plate 800 during loading the IC 215 in the socket 210. The slots 710 enable rotation of the compression plate 700. The posts 130 travel through the slots 710 as the compression plate 700 is rotated. The length of the slots 710 can be designed based on the amount of rotation of the compression plate 700 that is desired. Shorter slots 710 enable less rotation of the compression plate 700. Longer slots 710 enable greater rotation of the compression plate 700.

In some examples, the collar 115, the tightener 120, the compression plate 700, and/or the loading plate 800 are made of a metal. In some examples, the metal includes sheet metal and/or a flat-stock material.

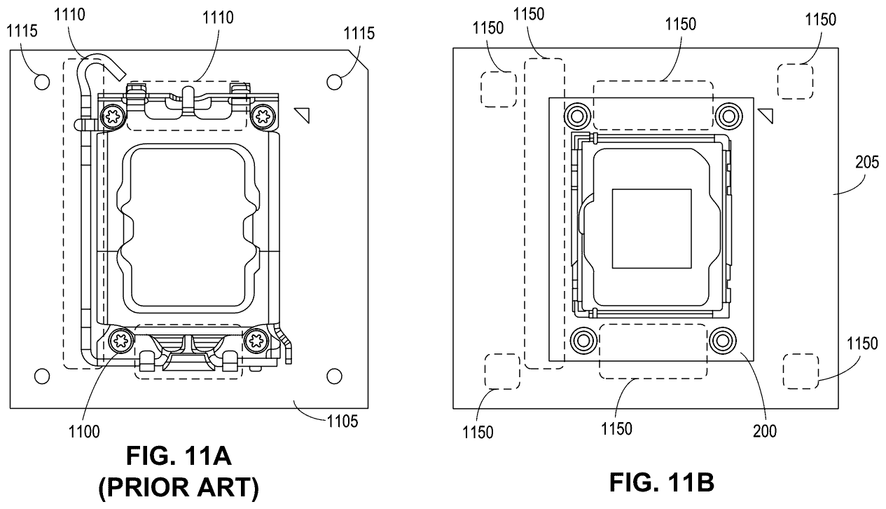

FIG. 11A illustrates the footprint of a conventional socket loading mechanism 1100 on a printed circuit board 1105. The conventional socket loading mechanism 1100 includes peripheral mechanical components 1110 that require physical space on the printed circuit board 1105. In addition, additional posts 1115 are needed to secure the conventional socket loading mechanism 1100 to the printed circuit board 1105. FIG. 11B illustrates the footprint of the socket loading mechanism 200 of FIG. 2 on the printed circuit board 205. The dashed boxes 1150 in FIG. 11B show spaces available on the printed circuit board 205 for wiring and/or other components. The spaces 1150 are formerly keep-out-zones in the conventional design shown in FIG. 11A. For example, through-holes in the printed circuit board have been reduced from eight to four. The reduction in keep-out-zones with the socket loading mechanism 200 disclosed herein enables more and/or less complex wiring in the printed circuit board 200. In addition, the socket loading mechanism 200 disclosed herein enables components (e.g., memories, capacitors, etc.) to be placed closer to the IC 215 than in prior designs. With components closer to the IC 215, there is less power loss and less decoupling capacitors are needed.

Example socket loading mechanism 200 disclosed herein also are scalable. If future or other alternative ICs use different (e.g., higher) loads to secure the IC in a socket, the ramp and/or cam design features such as height, angle, quantity, etc., can be adjusted to meet such designs.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

Example systems, apparatus, articles of manufacture, and methods are disclosed to load an integrated circuit (IC) into a socket. Example 1 includes an apparatus to load an IC in a socket includes: a collar; a tightener; a ramp carried by at least one of the collar or the tightener; and a cam carried by at least another one of the collar or the tightener, the cam engageable with the ramp, rotation of the tightener to cause relative movement between the cam and the ramp to displace the collar to apply a load to the IC.

Example 2 includes the apparatus of Example 1, including a handle to facilitate the rotation of the tightener.

Example 3 includes the apparatus of any preceding Example, including a heat sink, a first portion of the heat sink between the collar and the IC, and a second portion of the heat sink extending into a first aperture of the collar and a second aperture of the tightener.

Example 4 includes the apparatus of any preceding Example, wherein the tightener is ring-shaped.

Example 5 includes the apparatus of any preceding Example, including a sleeve to limit at least one of vertical or lateral displacement of the tightener.

Example 6 includes the apparatus of any preceding Example, wherein the ramp is a first ramp and the cam is a first cam, the collar including a second ramp, the tightener including a second cam, the second cam engageable with the second ramp.

Example 7 includes the apparatus of any preceding Example, including a spring to expand as the collar moves from a first position to a second position.

Example 8 includes an apparatus that includes a collar including a ramp; and a tightener including a central axis and a cam engageable with the ramp, the tightener rotatable about the central axis, rotation of the tightener to displace the collar along the central axis to load to an integrated circuit (IC) into a socket.

Example 9 includes the apparatus of any preceding Example, including a heat sink, a first portion of the heat sink between the collar and the IC, and a second portion of the heat sink extending along the central axis.

Example 10 includes the apparatus of any preceding Example, including a sleeve to limit displacement of the tightener along the central axis.

Example 11 includes the apparatus of any preceding Example, including a handle coupled to the tightener, the handle to facilitate rotation of the tightener, the handle extending through the sleeve.

Example 12 includes the apparatus of any preceding Example, including a post coupling the sleeve and the collar, the tightener between the sleeve the collar.

Example 13 includes the apparatus of any preceding Example, including a spring between the sleeve and the collar, the spring to apply force to the collar, the spring to expand as the collar moves along the central axis.

Example 14 includes an electronic device that includes a printed circuit board; an integrated circuit (IC); a socket to couple the IC to the printed circuit board; a collar, the IC between the collar and the socket; and a tightener on the collar, rotation of the tightener to displace the collar toward the socket and load the IC into the socket.

Example 15 includes the electronic device of any preceding Example, wherein rotation of the tightener to cause a cam to engage a ramp.

Example 16 includes the electronic device of any preceding Example, wherein the ramp includes a surface at an angle, and an amount of force on the IC as the collar is displaced is based on a magnitude of the angle.

Example 17 includes the electronic device of any preceding Example, including a heat sink between the IC and the collar.

Example 18 includes the electronic device of any preceding Example, wherein a portion of the heat sink extends through the collar and the tightener.

Example 19 includes the electronic device of any preceding Example, including: a sleeve; a backplate; and a post coupling the sleeve and the backplate, the post extending through the collar to prevent rotation of the collar.

Example 20 includes the electronic device of any preceding Example, including a spring between the sleeve and the collar, the spring to apply a force to the collar to displace the collar toward the socket.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus to load an integrated circuit (IC) in a socket, the apparatus comprising:
a collar;
a tightener;
a ramp carried by at least one of the collar or the tightener; and
a cam carried by at least another one of the collar or the tightener, the cam engageable with the ramp,
rotation of the tightener to cause relative movement between the cam and the ramp to displace the collar to apply a load to the IC.

2. The apparatus of claim 1, including a handle to facilitate the rotation of the tightener.

3. The apparatus of claim 1, including a heat sink, a first portion of the heat sink between the collar and the IC, and a second portion of the heat sink extending into a first aperture of the collar and a second aperture of the tightener.

4. The apparatus of claim 1, wherein the tightener is ring-shaped.

5. The apparatus of claim 1, including a sleeve to limit at least one of vertical or lateral displacement of the tightener.

6. The apparatus of claim 1, wherein the ramp is a first ramp and the cam is a first cam, the collar including a second ramp, the tightener including a second cam, the second cam engageable with the second ramp.

7. The apparatus of claim 1, including a spring to expand as the collar moves from a first position to a second position.

8. An apparatus comprising:
a collar including a ramp; and
a tightener including a central axis and a cam engageable with the ramp, the tightener rotatable about the central axis, rotation of the tightener to displace the collar along the central axis to load to an integrated circuit (IC) into a socket.

9. The apparatus of claim 8, including a heat sink, a first portion of the heat sink between the collar and the IC, and a second portion of the heat sink extending along the central axis.

10. The apparatus of claim 8, including a sleeve to limit displacement of the tightener along the central axis.

11. The apparatus of claim 10, including a handle coupled to the tightener, the handle to facilitate rotation of the tightener, the handle extending through the sleeve.

12. The apparatus of claim 10, including a post coupling the sleeve and the collar, the tightener between the sleeve the collar.

13. The apparatus of claim 12, including a spring between the sleeve and the collar, the spring to apply force to the collar, the spring to expand as the collar moves along the central axis.

14. An electronic device comprising:
a printed circuit board;
an integrated circuit (IC);
a socket to couple the IC to the printed circuit board;
a collar, the IC between the collar and the socket; and
a tightener on the collar, rotation of the tightener to displace the collar toward the socket and load the IC into the socket.

15. The electronic device of claim 14, wherein rotation of the tightener to cause a cam to engage a ramp.

16. The electronic device of claim 15, wherein the ramp includes a surface at an angle, and an amount of force on the IC as the collar is displaced is based on a magnitude of the angle.

17. The electronic device of claim 15, including a heat sink between the IC and the collar.

18. The electronic device of claim 17, wherein a portion of the heat sink extends through the collar and the tightener.

19. The electronic device of claim 14 including:
a sleeve;
a backplate; and
a post coupling the sleeve and the backplate, the post extending through the collar to prevent rotation of the collar.

20. The electronic device of claim 19, including a spring between the sleeve and the collar, the spring to apply a force to the collar to displace the collar toward the socket.
